(19) United States
(12) Patent Application Publication
(10) Pub. No.: US 2026/0324516 A1
(43) Pub. Date: Oct. 15, 2026

(54) THERMAL VIA INTERPOSER SUBSTRATE

(71) Applicant: QUALCOMM Incorporated, San Diego, CA (US)

(72) Inventors: Hyun-Il MOON, Suwon-si (KR); Kuiwon KANG, San Diego, CA (US); Joan Rey Villarba BUOT, Escondido, CA (US)

(21) Appl. No.: 19/296,720

(22) Filed: Aug. 11, 2025

Related U.S. Application Data
(60) Provisional application No. 63/789,255, filed on Apr. 15, 2025.

(51) Int. Cl. H10W 90/20; H10W 40/20; H10W 72/20

(52) U.S. Cl. CPC H10W 90/288; H10W 40/242; H10W 72/247

(57) ABSTRACT

Disclosed are die packages. The die package can include first and second dies with an interposer substrate there between. The ball grid array of the second dies can include signal and thermal balls. It is proposed to include thermal solder vias in the interposer substrate to carry heat from the first die to the thermal balls of the second die instead of conventional copper based vias and pads. In this way, better thermal performance may be expected.

### CROSS-REFERENCE TO RELATED APPLICATION

The present Application for Patent claims the benefit of U.S. Provisional Patent Application No. 63/789,255 entitled “THERMAL VIA INTERPOSER SUBSTRATE,” filed Apr. 15, 2025, assigned to the assignee hereof, and expressly incorporated herein by reference in its entirety.

### BACKGROUND OF THE DISCLOSURE

### 1. Field of the Disclosure

This disclosure relates generally to die packages or modules, and more specifically, but not exclusively, to packages with thermal via interposer substrate, e.g., for premium mobiles, and fabrication techniques thereof.

### 2. Description of the Related Art

Integrated circuit (IC) technology has achieved great strides in advancing computing power through miniaturization of active components. Conventional die packages include an interposer substrate between two active dies. In addition to providing signal paths, the interposer substrate can also transfer heat from a lower die to thermal pads of the upper die. However, the heat transfer capabilities of conventional interposer substrates may be insufficient. Also, the conventional interposer substrates use nickel-gold (Ni/Au) finish, which can increase costs. Accordingly, there is a need for systems, apparatus, and methods that overcome the deficiencies of conventional die packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary die package is disclosed. The die package may comprise a first die. The die package may also comprise an interposer substrate on the first die. The die package may further comprise a second die on the interposer substrate. The second die may comprise a ball grid array (BGA) on a lower surface of the second die. The BGA may comprise at least one signal ball and at least one thermal ball. The at least one signal ball may be configured to carry electrical signal to and/or from the second die. The interposer substrate may comprise a first dielectric layer stacked on a second dielectric layer. The interposer substrate may also comprise at least one thermal solder via within the first dielectric layer. A top portion of the at least one thermal solder via may be above an upper surface of the first dielectric layer. The at least one thermal solder via may be thermally coupled to the at least one thermal ball.

A method of fabricating a die package is disclosed. The method may comprise providing a first die. The method may also comprise forming an interposer substrate on the first die. The method may further comprise providing a second die on the interposer substrate. The second die may comprise a ball grid array (BGA) on a lower surface of the second die. The BGA may comprise at least one signal ball and at least one thermal ball. The at least one signal ball may be configured to carry electrical signal to and/or from the second die. The interposer substrate may comprise a first dielectric layer stacked on a second dielectric layer. The interposer substrate may also comprise at least one thermal solder via within the first dielectric layer. A top portion of the at least one thermal solder via may be above an upper surface of the first dielectric layer. The at least one thermal solder via may be thermally coupled to the at least one thermal ball.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a cross-sectional view of a die package with a conventional interposer substrate.

FIG. 1B illustrates a cross-sectional view of a conventional interposer substrate.

FIG. 2A illustrates a cross-sectional view of a die package with an interposer substrate in accordance with one or more aspects of the disclosure.

FIG. 2B illustrates a cross-sectional view of a first example of an interposer substrate in accordance with one or more aspects of the disclosure.

FIG. 3A-3C illustrate cross-sectional views of second, third, and fourth examples of interposer substrates in accordance with one or more aspects of the disclosure.

FIG. 4A-4G illustrate stages fabricating a first example interposer substrate in accordance with one or more aspects of the disclosure.

FIG. 5A-5H illustrate stages fabricating a second example interposer substrate in accordance with one or more aspects of the disclosure.

FIG. 6A-6H illustrate stages fabricating a third example interposer substrate in accordance with one or more aspects of the disclosure.

FIG. 7A-7I illustrate stages fabricating a fourth example interposer substrate in accordance with one or more aspects of the disclosure.

FIG. 8-12 illustrate flow charts of example methods of manufacturing a die package in accordance with at one or more aspects of the disclosure.

FIG. 13 illustrates various electronic devices which may utilize one or more aspects of the disclosure.

FIG. 14 illustrates a scan of an example die package.

FIG. 15 illustrates a more detailed scan of an example die package.

FIG. 16 illustrates a transition from conventional die packages with conventional interposer substrates to interposer substrates in accordance with one or more aspects of the disclosure.

FIG. 17 illustrates a die package with a conventional interposer substrate and summarizes issues associated with the conventional interposer substrate.

FIG. 18 illustrates examples of interposer substrates in accordance with one or more aspects of the disclosure.

FIGS. 19 and 20 illustrate examples of stages of fabricating a conventional interposer substrate and stages of fabricating interposer substrates in accordance with one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are die packages and methods for fabricating the same. In an aspect, the die package may comprise a first die, an interposer substrate on the first die, and a second die on the interposer substrate. The second die may comprise a ball grid array (BGA) on a lower surface of the second die. The BGA may comprise one or more signal balls and one or more thermal balls. The signal balls may be configured to carry electrical signal to and/or from the second die. The interposer substrate may comprise a first dielectric layer stacked on a second dielectric layer. The interposer substrate may also comprise at least one thermal solder via within the first dielectric layer. A top portion of the at least one thermal solder via may be above an upper surface of the first dielectric layer. The thermal solder vias may be thermally coupled to the thermal balls. Due to the sizes of the thermal solder vias, at least in part, the thermal performance of the interposer substrate may be enhanced. Also, the Ni/Au finish can be removed, which can reduce costs.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

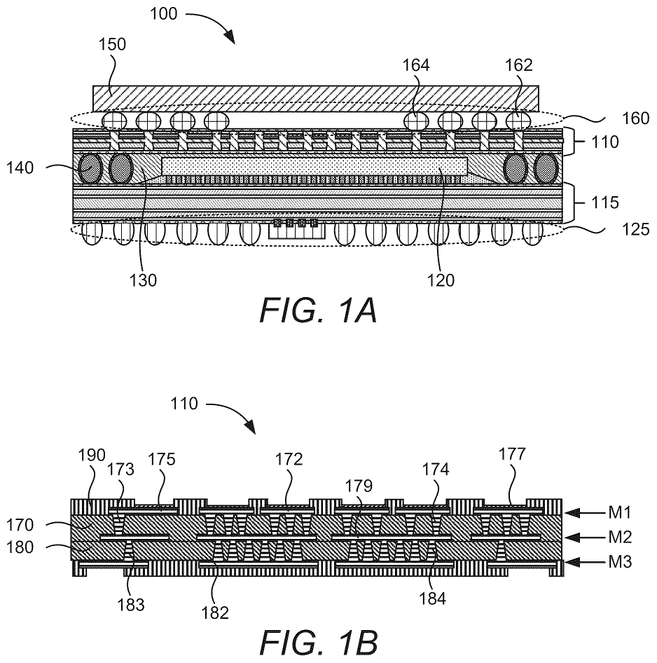

FIG. 1A illustrates a cross-sectional view of a die package 100 with a conventional interposer substrate 110. The die package 100 includes a first die 120 on a package substrate 115, an interposer substrate 110 on the first die 120, and a second die 150 on the interposer substrate 110. The second die 150 comprises a ball grid array (BGA) 160 on a lower surface thereof. The BGA 160 comprises a plurality of signal balls 162 configured to carry electrical signals to and/or from the second die 150. The BGA 160 also comprises a plurality of thermal balls 164 configured to dissipate heat from the first die 120. Mold 130 encapsulates the first die 120. Through mold vias (TMV) 140 are formed within the mold 130 and carries signals between the first and second dies 120, 150. Lower BGA 125 are formed on a lower surface of the package substrate 115 to carry signals to/from the first die 120 and/or the second die 150.

FIG. 1B illustrates a more detailed cross-sectional view of the interposer substrate 110, which includes a first dielectric layer 170 stacked on a second dielectric layer 180. A first metal layer M1 is on upper surface of the first dielectric layer 170, a second metal layer M2 is on upper surface of the of the second dielectric layer 180 and within the first dielectric layer 170, and a third metal layer M3 is on a lower surface of the second dielectric layer 180 and above the first die 120. First layer thermal pads 172 and first layer signal pads 175 are formed from the first metal layer M1, second layer thermal pads 179 are formed from the second metal layer M2, and third layer thermal pads 182 are formed from the third metal layer M3. The first layer thermal pads 172 correspond to the thermal balls 164.

Multiple lower thermal vias 184 and multiple lower signal vias 183 are formed within the second dielectric layer 180. The lower thermal vias 184 are in physical contact with the second and third layer thermal pads 179, 182. Also, multiple upper thermal vias 174 and multiple upper signal vias 173 are formed within the first dielectric layer 170. The upper thermal vias 174 are in physical contact with the first and second layer thermal pads 172, 179. In this way, heat from the first die 120 may be dissipated through a thermal path that includes the third layer thermal pads 182, the lower thermal vias 184, the second layer thermal pads 179, the upper thermal vias 174, the first layer thermal pads 172, and the thermal balls 164.

The lower signal vias 183 are in physical contact with the signal pads of the second and third metal layers M2, M3. Also, the upper signal vias 173 are in physical contact with the first layer signal pads 175 (of the first metal layer M1) and the signal pad of the second metal layer M2. In this way, electrical signal and/or power may be provided to the first die 120 and/or the second die 150. Solder resists (SR) 190 are formed on the upper surface of the first dielectric layer 170 and on the lower surface of the second dielectric layer 180. Further, nickel/gold (Ni/Au) finish 177 is formed on upper surfaces of the first layer signal pads 175.

As indicated above, heat from the first die 120 is dissipated through the thermal path that includes the upper thermal vias 174 formed within the first dielectric layer 170. Due to the small size and small density of the upper thermal vias 174, the capacity to transfer heat is limited. Also, the Ni/Au finish 177 can increase costs.

To address these and other issues of the conventional die package, it is proposed to provide incorporate solder vias into the thermal path. The solder vias are relatively large, and thus can enhance thermal dissipation properties. Also, solder finish can replace the Ni/Au finish, which can decrease costs.

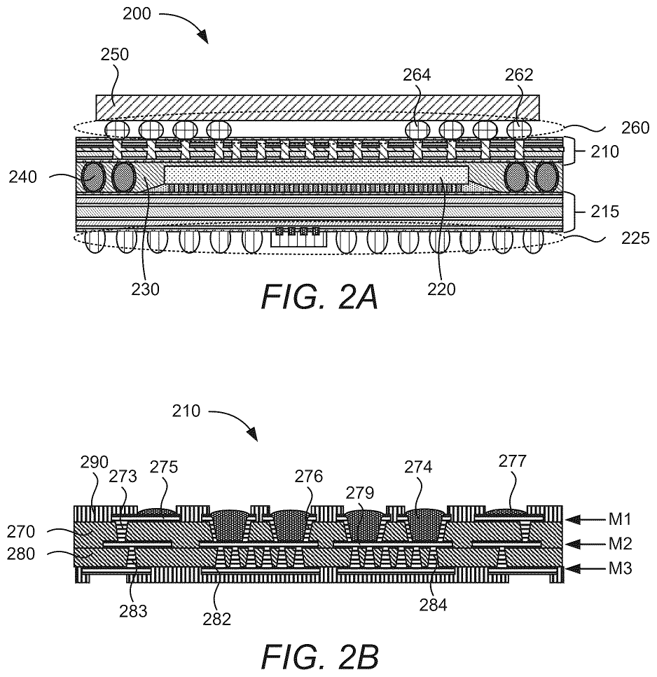

FIG. 2A illustrates a cross-sectional view of a die package 200 with an interposer substrate 210 in accordance with one or more aspects of the disclosure. The die package 200 may include a first die 220 on a package substrate 215, the interposer substrate 210 on the first die 220, and a second die 250 on the interposer substrate 210. The second die 250 may comprise a ball grid array (BGA) 260 on a lower surface thereof. The BGA 260 may comprise one or more signal balls 262 configured to carry electrical signals to and/or from the second die 250. The BGA 260 may also comprise one or more thermal balls 264 configured to dissipate heat from the first die 220. Mold 230 may encapsulate the first die 220. The mold 230 may be made from materials such as epoxy resins, organic resins, sealants, etc. Through mold vias (TMV) 240 may be formed within the mold 230 and may carry signals between the first and second dies 220, 250. Lower BGA 225 may be formed on a lower surface of the package substrate 215 and may carry signals to/from the first die 220 and/or the second die 250.

FIG. 2B illustrates a more detailed cross-sectional view of the interposer substrate 210. The interposer substrate 210 may be viewed as an example of a 3L coreless substrate. In coreless substrates, multiple thin layers of conductive and insulating material may be used. The interposer substrate 210 may include a first dielectric layer 270 stacked on a second dielectric layer 280. That is, lower surface of the first dielectric layer 270 may be in physical contact with upper surface of the second dielectric layer 280.

A first metal layer M1 may be formed on upper surface of the first dielectric layer 270. A second metal layer M2 may be formed on upper surface of the of the second dielectric layer 280. The second metal layer M2 may be within the first dielectric layer 270. A third metal layer M3 may be formed on lower surface of the second dielectric layer 280. The third metal layer M3 may be above the first die 220. In an aspect, any of the first, second, and third metal layers M1, M2, M3 may be formed from copper (Cu).

One or more first layer signal pads 275 may be formed from the first metal layer M1. Unlike the conventional interposer substrate 110, first layer thermal pads are not necessary. Second layer signal pads and second layer thermal pads 279 may be formed from the second metal layer M2. Further, third layer thermal pads 282 and third layer signal pads may be formed from the third metal layer M3.

One or more lower thermal vias 284 and one or more lower signal vias 283 may be formed within the second dielectric layer 280. The lower thermal vias 284 may be thermally coupled to the second and third layer thermal pads 279, 282. For example, lower thermal vias 284 may be in physical contact with lower surface of the second layer thermal pads 279 and with upper surface of the third layer thermal pads 282. The lower signal vias 283 may be electrically coupled with the second and third layer signal pads, e.g., the lower signal vias 283 may be in physical contact with lower surface of the second layer signal pads and with upper surface of the third layer signal pads. One or more upper signal vias 273 may be formed within the first dielectric layer 270. The upper signal vias 273 may be electrically coupled to the second and third layer signal pads. For example, the upper signal vias 273 may be in physical contact with lower surface of the first layer signal pads 275 and with upper surface of the second layer signal pads. Any of the lower thermal vias 284, lower signal vias 283, and upper signal vias 273 may be formed from metal such as copper.

One or more thermal solder vias 274 may be formed at least within the first dielectric layer 270. The locations of the thermal solder vias 274 may correspond to the locations of the thermal balls 264. For example, they may vertically overlap, at least in part. As a result, the thermal solder vias 274 may be thermally coupled to the corresponding thermal balls 264. For example, the thermal solder vias 274 may be in physical contact with the corresponding thermal balls 264. In this way heat from the first die 220 may be dissipated through a thermal path that includes the third layer thermal pads 282, the lower thermal vias 284, the second layer thermal pads 279, the thermal solder vias 274, and the thermal balls 264. Due to the relatively large sizes of the thermal solder vias 274, heat dissipation properties of the interposer substrate 210 may be enhanced. Note that in an aspect, the thermal solder vias 274 need not carry any electrical signals to/from the first die 220 and/or the second die 250.

Top portions of the thermal solder vias 274 may be above the upper surface of the first dielectric layer 270. Also, note that thermal via metals 276 may be formed on sides of the thermal solder vias 274. In an aspect, the thermal via metals 276 may be formed from metals such as copper. Solder resists (SR) 290 may be formed on the upper surface of the first dielectric layer 270 and on the lower surface of the second dielectric layer 280. Further, instead of the Ni/Au finish, solder finish 277 may be formed on upper surfaces of the first layer signal pads 275. While not shown, there may be more than three metal layers metals. Also while note shown, there may be more than two dielectric layers.

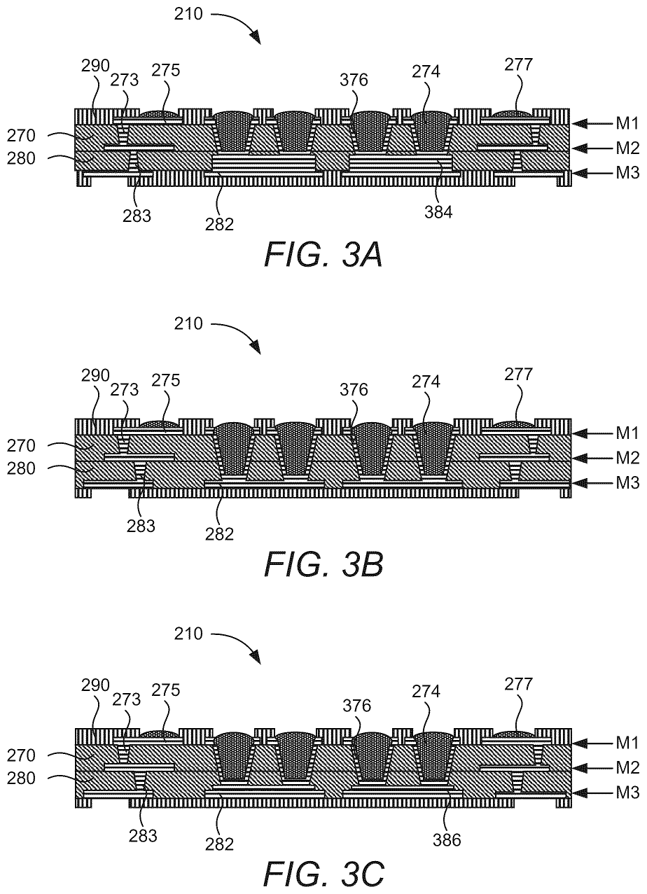

As noted above, FIG. 2B illustrates an example of a 3L coreless substrate. However, there can be variations to the interposer substrate. FIG. 3A illustrates an example of an interposer substrate with a 3L coreless with metal block. For sake of brevity, only the differences from FIG. 2B will be discussed. As seen in FIG. 3A, the thermal via metals 376 may be formed on the lower surface thermal solder vias 274 in addition to the side surfaces. Also, instead of the lower thermal vias 284, one or more metal blocks 384 may be formed within the second dielectric layer 280. The metal blocks 384 may be thermally coupled to the thermal via metals 376. For example, the metal blocks 384 may be in physical contact with the lower surfaces of the thermal via metals 376. In an aspect, the metal blocks 384 may be formed from metals such as Cu.

FIG. 3B illustrates an example of an interposer substrate with a 3L embedded trace substrate (ETS). In ETS, conductive traces may be embedded within the substrate material instead of its surface. Again, differences from FIG. 2B will be discussed. In FIG. 3B, there are no lower thermal vias 284. Instead, in this instance, the one or more thermal solder vias 274 may be formed within both the first and second dielectric layers 270, 280. Also, the thermal via metals 376 may be formed on the lower surface thermal solder vias 274 in addition to the side surfaces. The third layer thermal pads 282 may be thermally coupled to the thermal via metals 376. For example, the third layer thermal pads 282 may be in physical contact with the lower surfaces of the thermal via metals 376. In an aspect, the thermal via metals 376 may be formed from metals such as Cu.

FIG. 3C illustrates an example of an interposer substrate with a 3L ETS with metal (e.g., Cu) post/stud. Yet again, differences from FIG. 2B will be discussed. In FIG. 3C, there are no lower thermal vias 284. Instead, in this instance, the one or more thermal solder vias 274 may be formed within both the first and second dielectric layers 270, 280. Also, the thermal via metals 376 may be formed on the lower surface thermal solder vias 274 in addition to the side surfaces. One or more metal posts 386 may be formed within the second dielectric layer 280. The metal posts 386 may be thermally coupled to the thermal via metals 376 and the third layer thermal pads 282. For example, the metal posts 386 may be in physical contact with lower surfaces of the thermal via metal 376 and with upper surfaces of the third layer thermal pads 282.

While not shown, it is contemplated that the package substrate 215 may be formed similar to the interposer substrate 210. That is, the package substrate 215 may comprise one or more metal layers (e.g., similar to metal layers M1, M2, M, etc.), and one or more dielectric layers. Such package substrate 215 may further dissipate heat from the first die 220. Signal and thermal pads may be formed in the package substrate 215 along with signal and thermal vias. Also, the package substrate 215 may comprise thermal solder vias, metal blocks and/or metal posts. Physically, the package substrate 215 may be flipped relative to the interposer substrate 210. That is, the thermal solder vias of the package substrate 215 may be thermally coupled to (e.g., in contact with) thermal balls of the lower BGA 225.

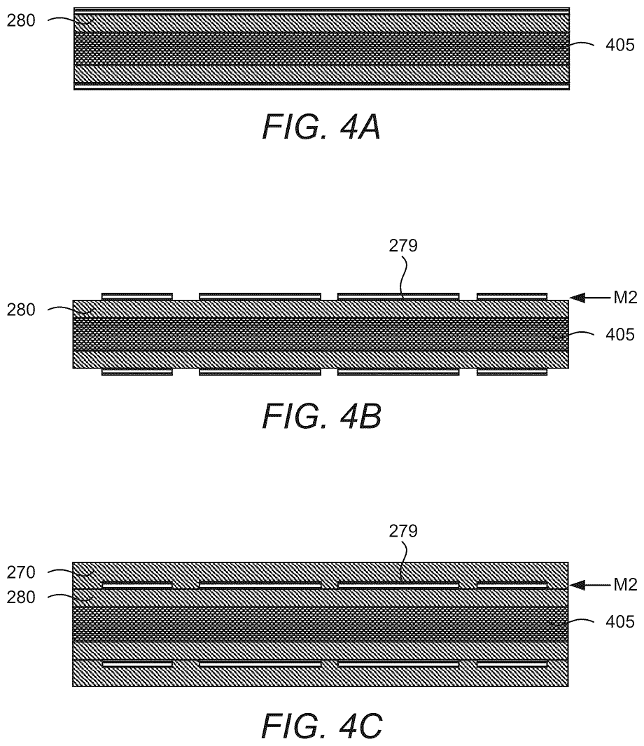

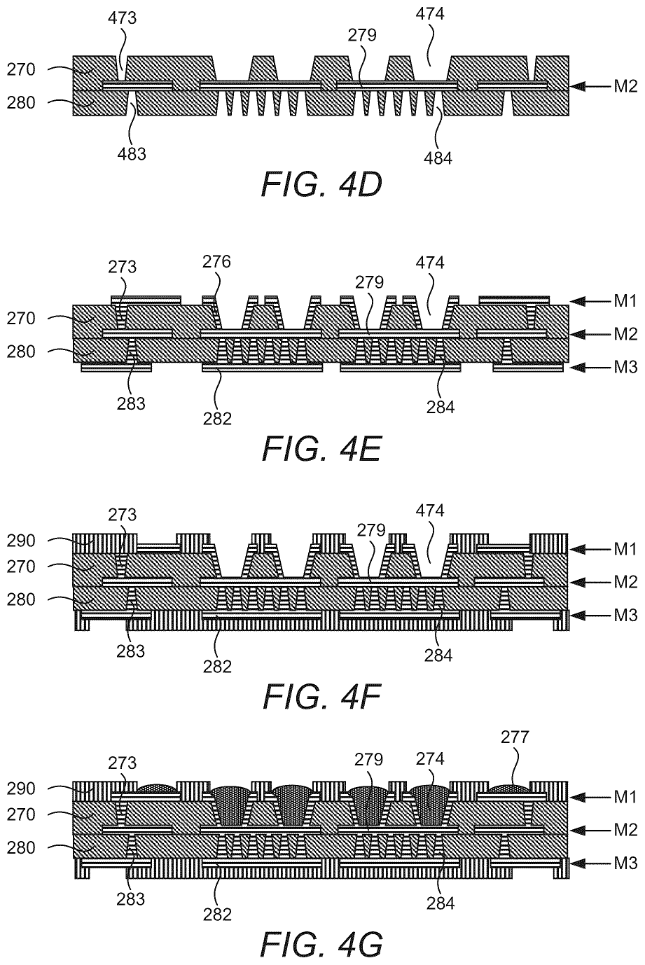

FIG. 4A-4G, 5A-5H, 6A-6H and 7A-7I illustrate stages fabricating various example interposer substrates in accordance with one or more aspects of the disclosure. In these figures, forming die packages on both sides of a carrier is shown. However, this is an example, and should not be taken to be a limitation. That is, it is also contemplated that die packages may be formed on one side of a carrier. Also, in this instance, description of the process taken on the side above the carrier will be provided. However, similar processes may be performed on the side below the carrier.

FIG. 4A-4G illustrate stages fabricating the interposer substrate illustrated in FIG. 2B in accordance with one or more aspects of the disclosure.

FIG. 4A illustrates a stage in which the second dielectric layer 280 may be formed on a carrier 405.

FIG. 4B illustrates a stage in which the second metal layer M2 may be patterned on the second dielectric layer 280 to form the second layer thermal and signal pads.

FIG. 4C illustrates a stage in which the first dielectric layer 270 may be formed on the second dielectric layer 280 and on the second metal layer M2;

FIG. 4D illustrates a stage in which etching and/or drilling may be performed on both the first and second dielectric layers 270, 280. Here, it may be assumed that the carrier 405 has been separated. Drilling the first dielectric layer 270 may form one or more upper signal via holes 473 to expose upper surfaces of the second layer signal pads and may form one or more thermal solder via holes 474 to expose upper surfaces of the second layer thermal pads 279. Drilling the second dielectric layer 280 may form one or more lower signal via holes 483 to expose lower surfaces of the second layer signal pads and may form a plurality of lower thermal via holes 484 to expose the lower surfaces of the second layer thermal pads 279.

FIG. 4E illustrates a stage in which the first metal layer M1 and the third metal layer M3 may be patterned. The first metal layer M1 may be patterned on the first dielectric layer 270, in the thermal solder via holes 474, and in the one or more upper signal via holes 473. As a result, thermal via metals 276 may be formed on sides of the thermal solder via holes 474. Also, the one or more upper signal vias 273 may be formed. The third metal layer M3 may be patterned on the lower surface of the second dielectric layer 280, in the plurality of lower thermal via holes 484, and in the one or more lower signal via holes 483. As a result, the plurality of lower thermal vias 284 and the one or more lower signal vias 283 may be formed.

FIG. 4F illustrates a stage in which solder resist (SR) 290 may be formed on the upper surface of the first dielectric layer 270, on the lower surface of the second dielectric layer 280, or both.

FIG. 4G illustrates a stage in which the thermal solder via holes may be filled with solder to form the thermal solder vias 274.

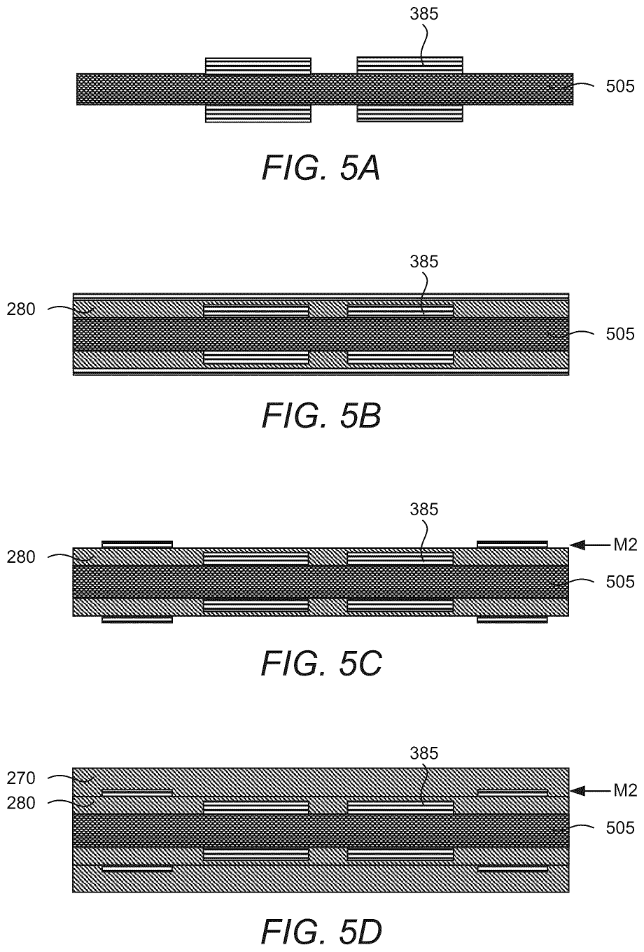

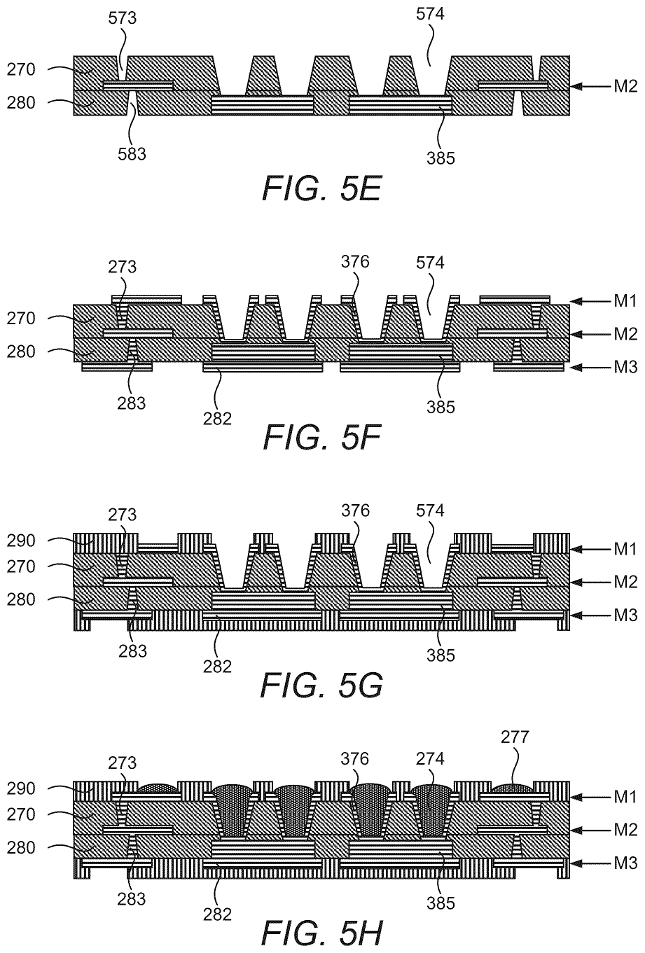

FIG. 5A-5H illustrate stages fabricating the interposer substrate illustrated in FIG. 3A in accordance with one or more aspects of the disclosure.

FIG. 5A illustrates a stage in which one or more metal blocks 385 may be formed on a carrier 505.

FIG. 5B illustrates a stage in which the second dielectric layer 280 may be formed on the carrier 505 and on the one or more metal block 385.

FIG. 5C illustrates a stage in which the second metal layer M2 may be patterned on the second dielectric layer 280 to form the second layer thermal and signal pads.

FIG. 5D illustrates a stage in which the first dielectric layer 270 may be formed on the second dielectric layer 280 and on the second metal layer M2.

FIG. 5E illustrates a stage in which etching and/or drilling may be performed on both the first and second dielectric layers 270, 280. Here, it may be assumed that the carrier 505 has been separated. Drilling the first dielectric layer 270 and partially drilling the second dielectric layer 280 may form one or more thermal solder via hole 574 to expose upper surfaces of the one or more metal block 385. Drilling the first dielectric layer 270 may form one or more upper signal via holes 573 to expose upper surfaces of the one or more second layer signal pads.

FIG. 5F illustrates a stage in which a stage in which the first metal layer M1 and the third metal layer M3 may be patterned. The first metal layer M1 may be patterned on the first dielectric layer 270, in the thermal solder via holes 574, and in the one or more upper signal via holes 573. As a result, thermal via metals 376 may be formed on sides and bottom of the thermal solder via holes 474. Also, the one or more upper signal vias 273 may be formed. The third metal layer M3 may be patterned on the lower surface of the second dielectric layer 280 and on the lower surface of the one or more metal blocks 385. As a result, the one or more lower signal vias 283 may be formed.

FIG. 5G illustrates a stage in which solder resist (SR) 290 may be formed on the upper surface of the first dielectric layer 270, on the lower surface of the second dielectric layer 280, or both.

FIG. 5H illustrates a stage in which the one or more thermal solder via holes 574 may be filled with solder to form the one or more thermal solder via 274.

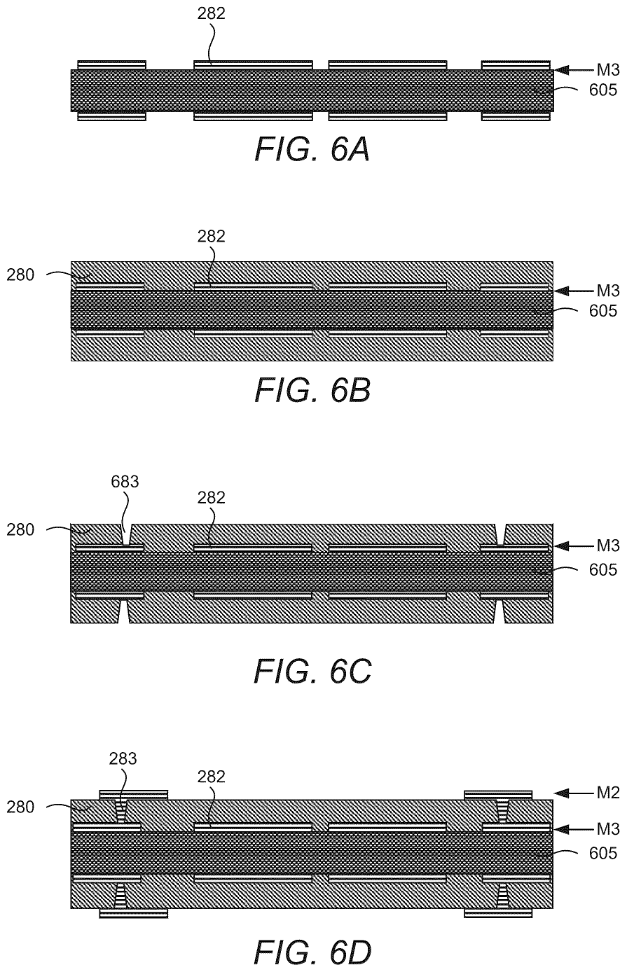

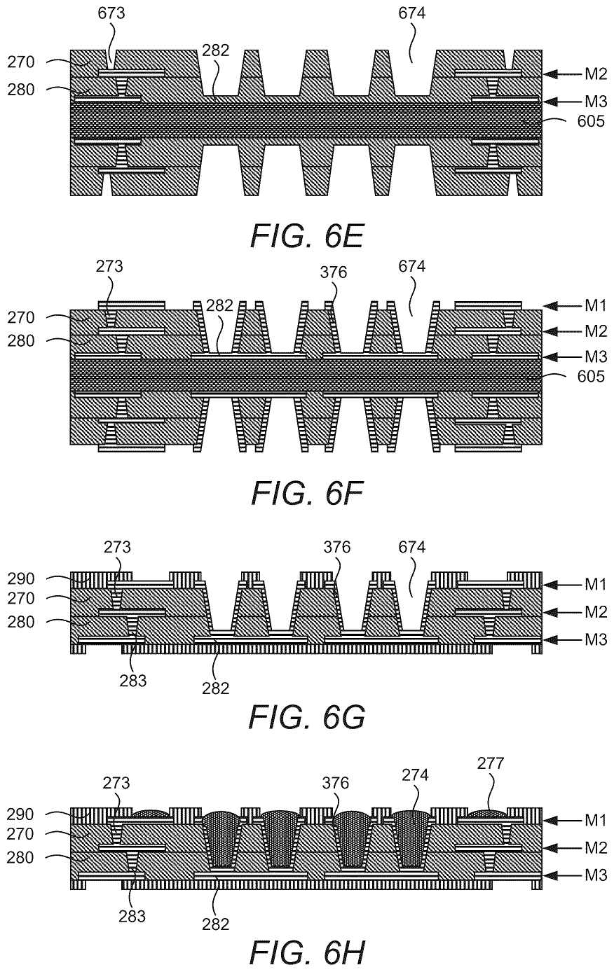

FIG. 6A-6H illustrate stages fabricating the interposer substrate illustrated in FIG. 3B in accordance with one or more aspects of the disclosure.

FIG. 6A illustrates a stage in which the third metal layer M3 may be patterned on a carrier 605.

FIG. 6B illustrates a stage in which the second dielectric layer 280 may be formed on the carrier 605 and on the third metal layer M2.

FIG. 6C illustrates a stage in which the second dielectric layer 280 may be etched/drilled to form one or more lower signal via holes 683.

FIG. 6D illustrates a stage in which the second metal layer M2 may be patterned on the second dielectric layer 280.

FIG. 6E illustrates a stage in which the first dielectric layer 270 may be formed on the second dielectric layer 280 and on the second metal layer M2. FIG. 6E also illustrates that etching and/or drilling may be performed on both the first and second dielectric layers 270, 280. Drilling the first dielectric layer 270 may form one or more upper signal via holes 673 to expose upper surfaces of the one or more second layer signal pads. Drilling the first and second dielectric layers 270, 280 may form one or more thermal solder via holes 674 to expose upper surfaces of the one or more third layer thermal pads 282.

FIG. 6F illustrates a stage in which the first metal layer M1 may be patterned on the first dielectric layer 270, in the one or more thermal solder via holes 674, and the one or more upper signal via holes 673. As a result, one or more thermal via metals 376 and one or more upper signal vias 273 may be formed.

FIG. 6G illustrates a stage in which solder resist (SR) 290 may be formed on the upper surface of the first dielectric layer 270, on the lower surface of the second dielectric layer 280, or both. Here, it may be assumed that the carrier 605 has been separated.

FIG. 6H illustrates a stage in which the one or more thermal solder via hole 674 may be filled with solder to form the one or more thermal solder vias 274.

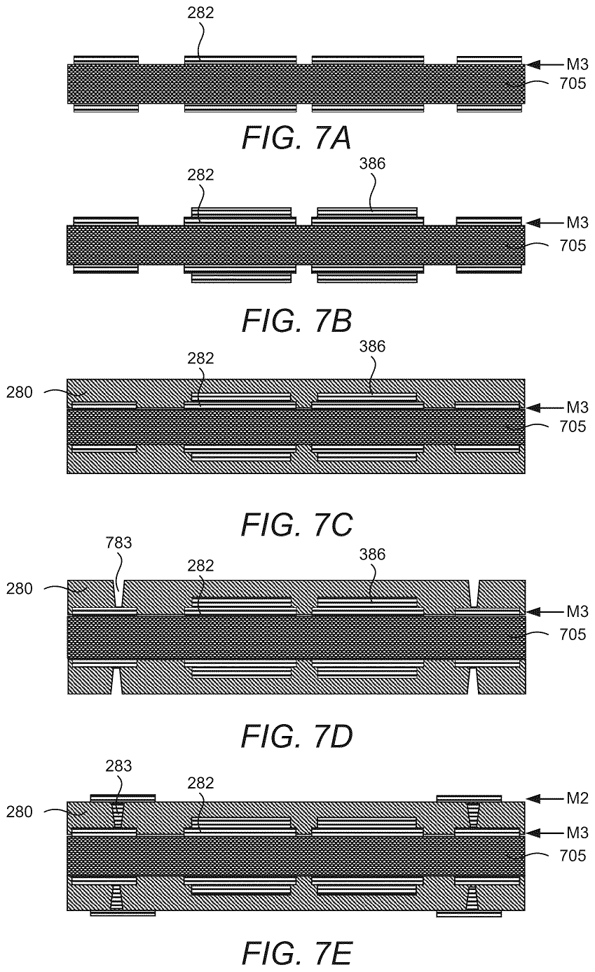

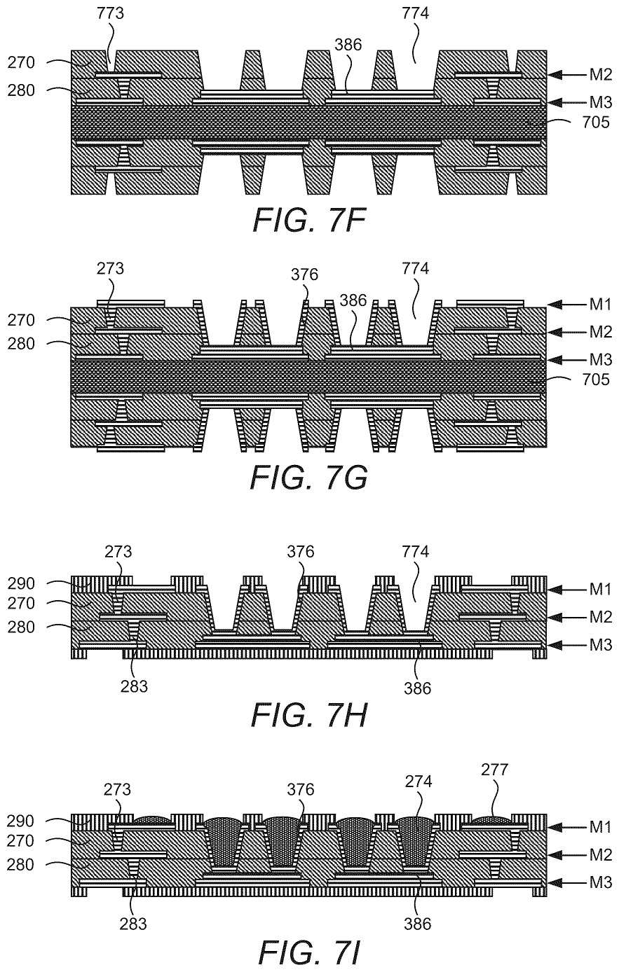

FIG. 7A-7I illustrate stages fabricating the interposer substrate illustrated in FIG. 3C in accordance with one or more aspects of the disclosure.

FIG. 7A illustrates a stage in which the third metal layer M3 may be patterned on a carrier 705.

FIG. 7B illustrates a stage in which the one or more metal posts 386 may be formed on the one or more third layer thermal pad 282.

FIG. 7C illustrates a stage in which the second dielectric layer 280 may be formed on the carrier 705, on the third metal layer M3, and on the one or more third layer thermal pads 282.

FIG. 7D illustrates a stage in which the second dielectric layer 280 may be etched or drilled to form one or more lower signal via holes 783.

FIG. 7E illustrates a stage in which the second metal layer M2 may be patterned on the second dielectric layer 280.

FIG. 7F illustrates a stage in which the first dielectric layer 270 may be formed on the second dielectric layer 280 and on the second metal layer M2. FIG. 7F also illustrates that etching and/or drilling may be performed on both the first and second dielectric layers 270, 280. Drilling the first dielectric layer 270 may form one or more upper signal via holes 773 to expose upper surfaces of the one or more second layer signal pads. Drilling the first and second dielectric layers 270, 280 may form one or more thermal solder via holes 774 to expose upper surfaces of the one or more metal posts 386.

FIG. 7G illustrates a stage in which the first metal layer M1 may be patterned on the first dielectric layer 270 and in the one or more thermal solder via hole 774. As a result, the one or more thermal via metals 376 may be formed.

FIG. 7H illustrates a stage in which solder resist SR 290 may be formed on the upper surface of the first dielectric layer 270, on the lower surface of the second dielectric layer 280, or both.

FIG. 7I illustrates a stage in which the one or more thermal solder via hole 774 may be filled with solder to form the one or more thermal solder vias 274.

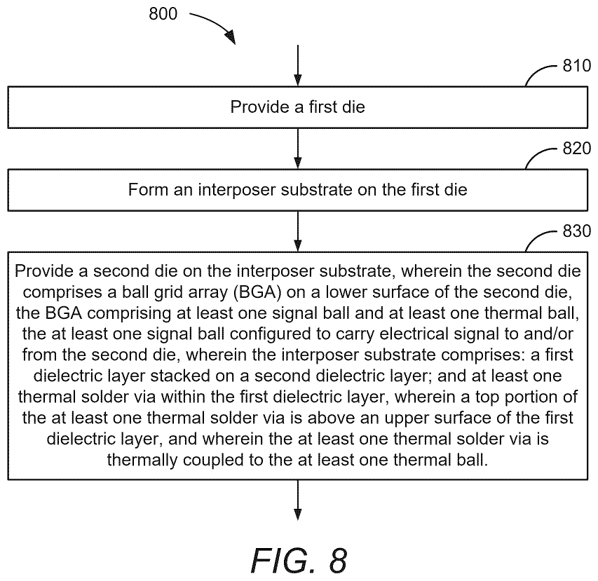

FIG. 8 illustrates a flow chart of an example method 800 of fabricating a die package, such as the die package 200, in accordance with at one or more aspects of the disclosure.

In block 810, a first die 220 may be provided.

In block 820, an interposer substrate 210 may be formed on the first die 220.

In block 830, a second die 250 may be provided on the interposer substrate 210. The second die may comprise a ball grid array (BGA) on a lower surface of the second die. The BGA may comprise at least one signal ball and at least one thermal ball. The at least one signal ball may be configured to carry electrical signal to and/or from the second die. The interposer substrate may comprise a first dielectric layer stacked on a second dielectric layer. The interposer substrate may also comprise at least one thermal solder via within the first dielectric layer. A top portion of the at least one thermal solder via may be above an upper surface of the first dielectric layer. The at least one thermal solder via may be thermally coupled to the at least one thermal ball.

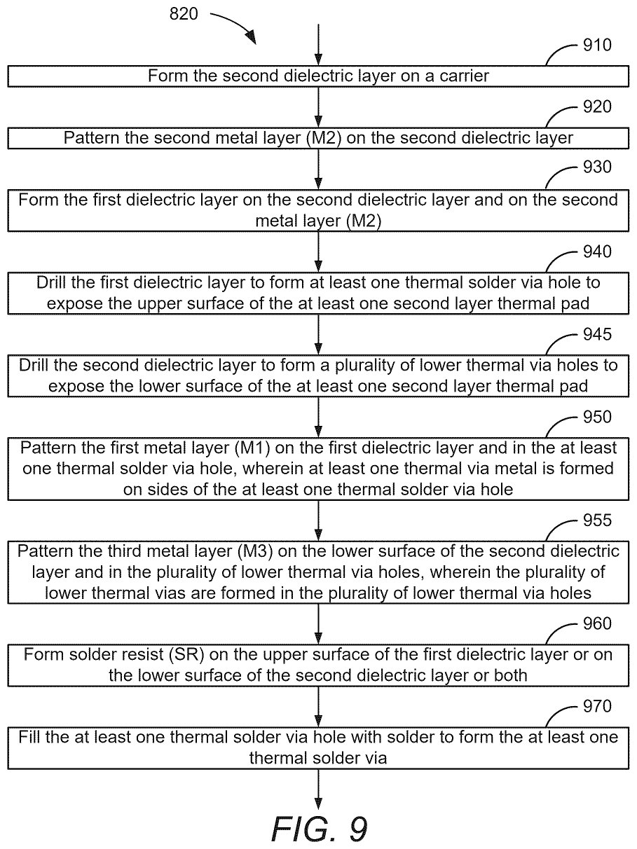

FIG. 9 illustrates a flow chart of an example process to perform block 820 of FIG. 8. The process of FIG. 9 corresponds to the stages illustrated in FIG. 4A-4G.

In block 910, the second dielectric layer 280 may be formed on a carrier 405.

In block 920, the second metal layer M2 may be patterned on the second dielectric layer 280.

In block 930, the first dielectric layer 270 may be formed on the second dielectric layer 280 and on the second metal layer M2.

In block 940, the first dielectric layer 270 may be drilled to form at least one thermal solder via hole 474 to expose the upper surface of the at least one second layer thermal pad 279.

In block 945, the second dielectric layer 280 may be drilled to form a plurality of lower thermal via holes 484 to expose the lower surface of the at least one second layer thermal pad 279.

In block 950, the first metal layer M1 may be patterned on the first dielectric layer 270 and in the at least one thermal solder via hole 474. At least one thermal via metal 276 may be formed on sides of the at least one thermal solder via hole 474.

In block 955, the third metal layer M3 may be patterned on the lower surface of the second dielectric layer 280 and in the plurality of lower thermal via holes 484. The plurality of lower thermal vias 284 may be formed in the plurality of lower thermal via holes 484.

In block 960, solder resist (SR) 290 may be formed on the upper surface of the first dielectric layer 270 or on the lower surface of the second dielectric layer 280 or both.

In block 970, the at least one thermal solder via hole 474 may be filed with solder to form the at least one thermal solder via 274.

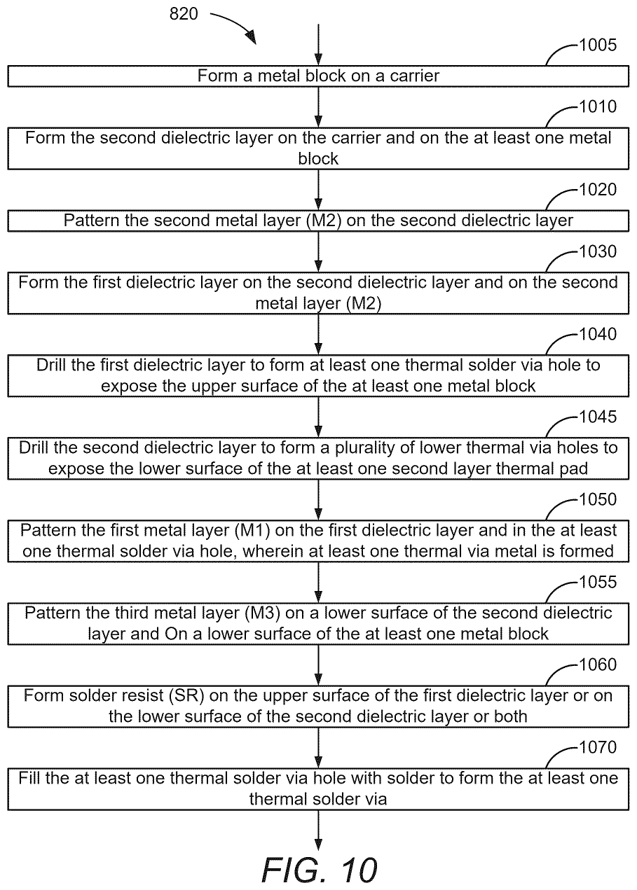

FIG. 10 illustrates a flow chart of an example process to perform block 820 of FIG. 8. The process of FIG. 10 corresponds to the stages illustrated in FIG. 5A-5H.

In block 1005, at least one metal block 385 may be formed on a carrier 505.

In block 1010, the second dielectric layer 280 may be formed on the carrier 505 and on the at least one metal block 385.

In block 1020, the second metal layer M2 may be patterned on the second dielectric layer 280.

In block 1030, the first dielectric layer 270 may be formed on the second dielectric layer 280 and on the second metal layer M2.

In block 1040, the first dielectric layer 270 and the second dielectric layer 280 may be drilled to form at least one thermal solder via hole 574 to expose upper surface of the at least one metal block 385.

In block 1050, the first metal layer M1 may be patterned on the first dielectric layer 270, wherein the at least one thermal via metal 376 may be formed.

In block 1050, the third metal layer M3 may be patterned on the lower surface of the second dielectric layer 280 and on a lower surface of the at least one metal block 385.

In block 1060, solder resist (SR) 290 may be formed on the upper surface of the first dielectric layer 270 or on the lower surface of the second dielectric layer 280 or both.

In block 1070, the at least one thermal solder via hole 574 may be filed with solder to form the at least one thermal solder via 274.

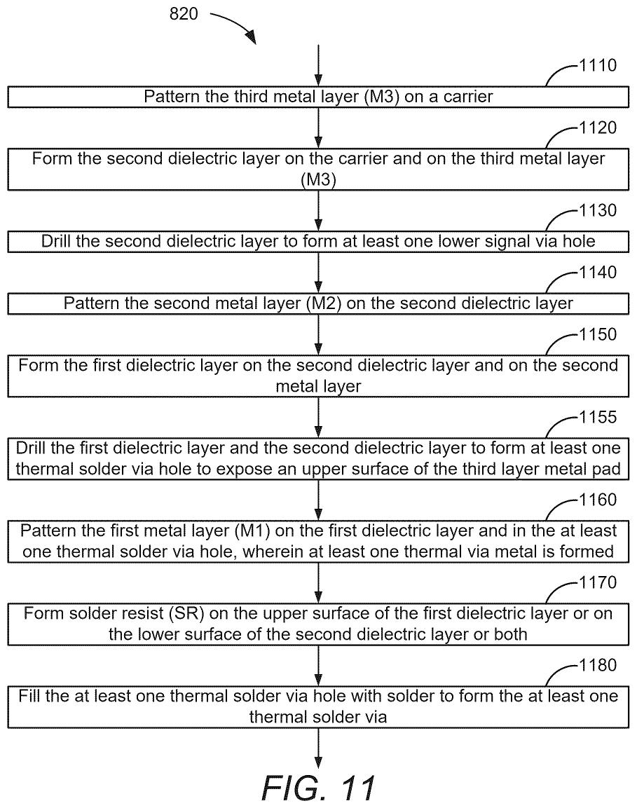

FIG. 11 illustrates a flow chart of an example process to perform block 820 of FIG. 8. The process of FIG. 11 corresponds to the stages illustrated in FIG. 6A-6H.

In block 1110, the third metal layer M3 may be patterned on a carrier 605.

In block 1120, the second dielectric layer 280 may be formed on the carrier 605 and on the third metal layer M2.

In block 1130, the second dielectric layer 280 may be drilled to form at least one lower signal via hole 683.

In block 1140, the second metal layer M2 may be patterned on the second dielectric layer 280.

In block 1150, the first dielectric layer 270 may be formed on the second dielectric layer 280 and on the second metal layer M2.

In block 1155, the first dielectric layer 270 and the second dielectric layer 280 may be drilled to form at least one thermal solder via hole 674 to expose an upper surface of the third layer thermal pad 282.

In block 1160, the first metal layer M1 may be patterned on the first dielectric layer 270 and in the at least one thermal solder via hole 674. The at least one thermal via metal 376 may be formed.

In block 1170, solder resist (SR) 290 may be formed on the upper surface of the first dielectric layer 270 or on the lower surface of the second dielectric layer 280 or both.

In block 1180, the at least one thermal solder via hole 674 may be filled with solder to form the at least one thermal solder via 274.

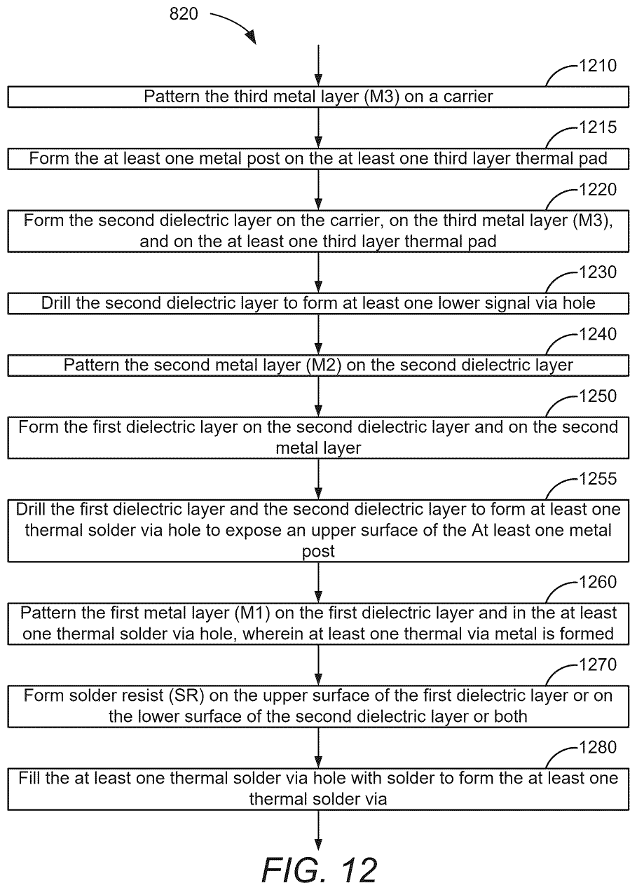

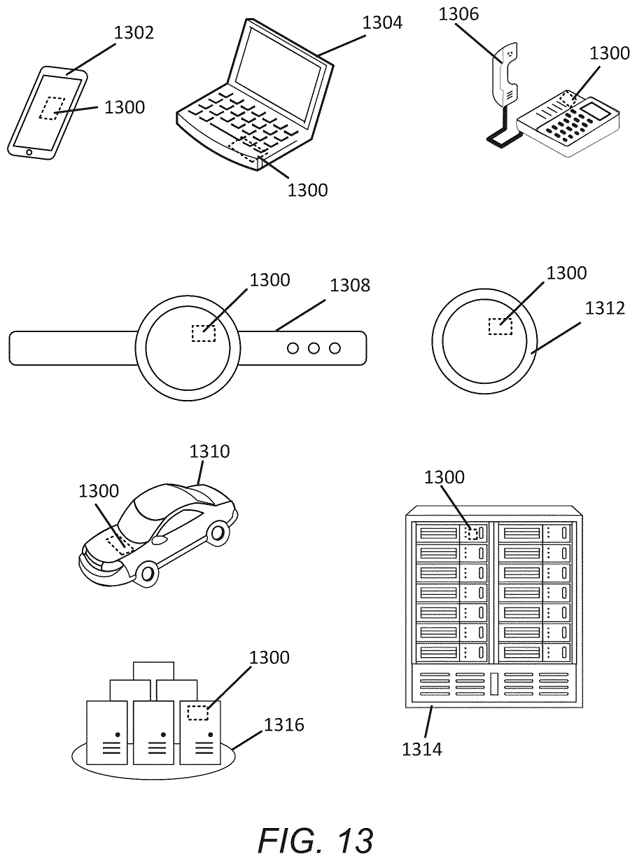

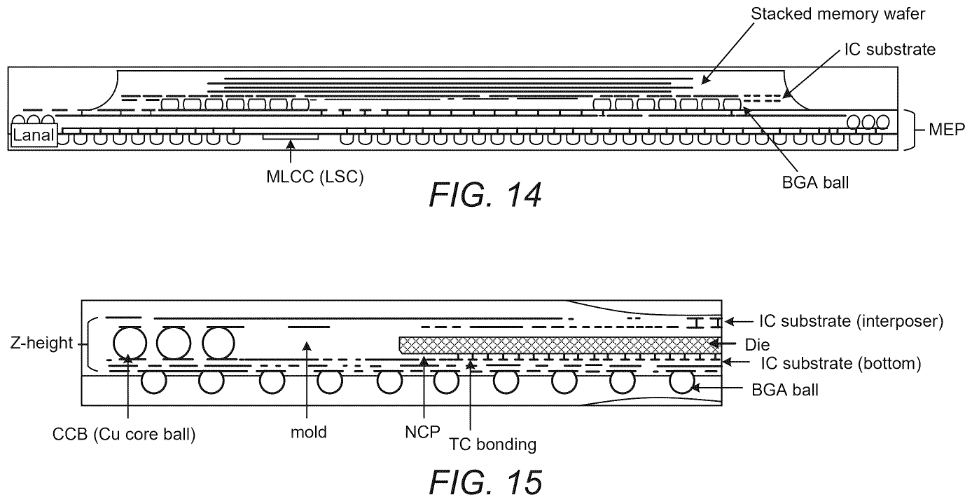

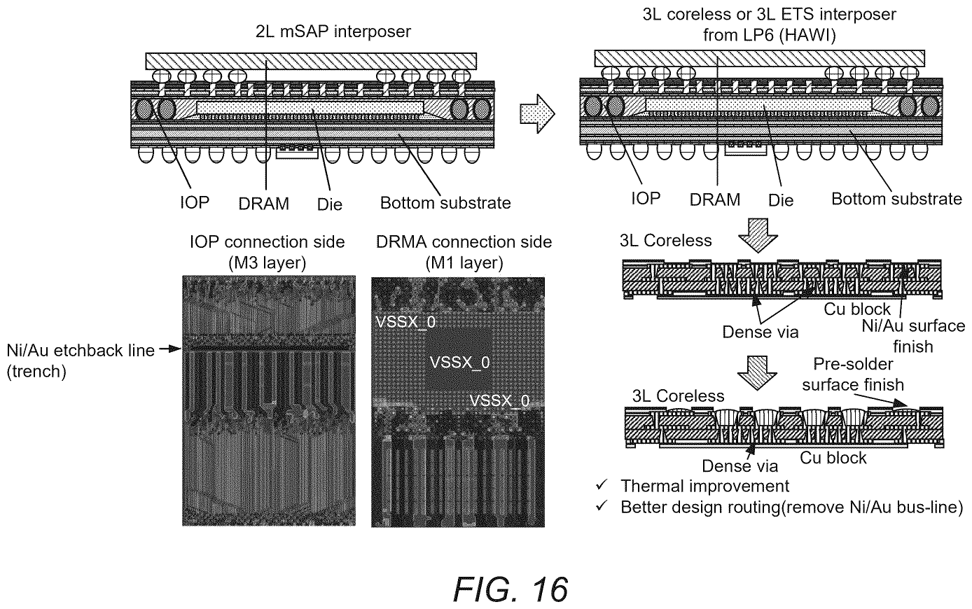

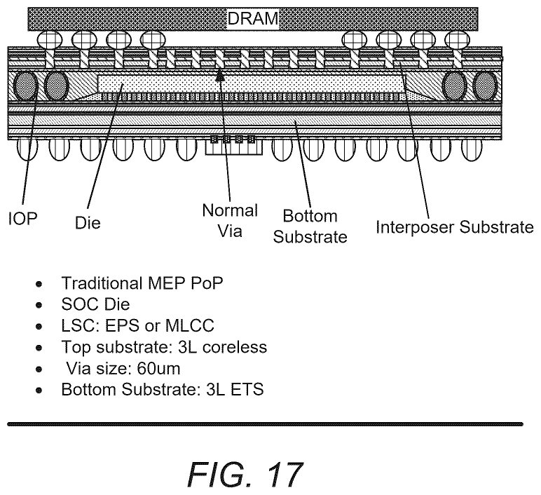

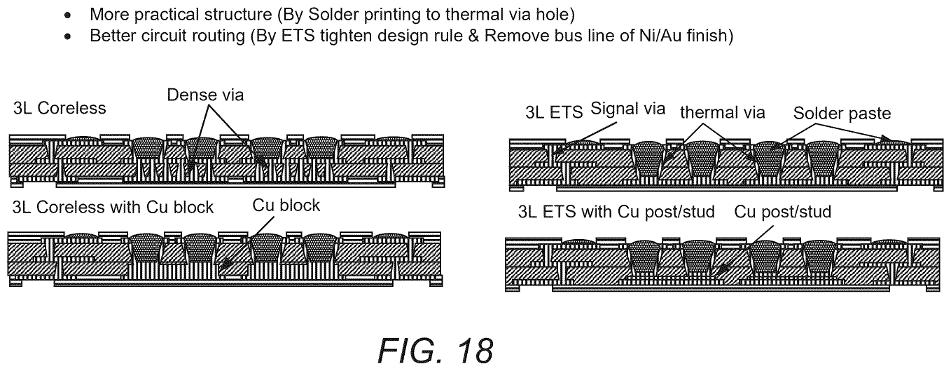

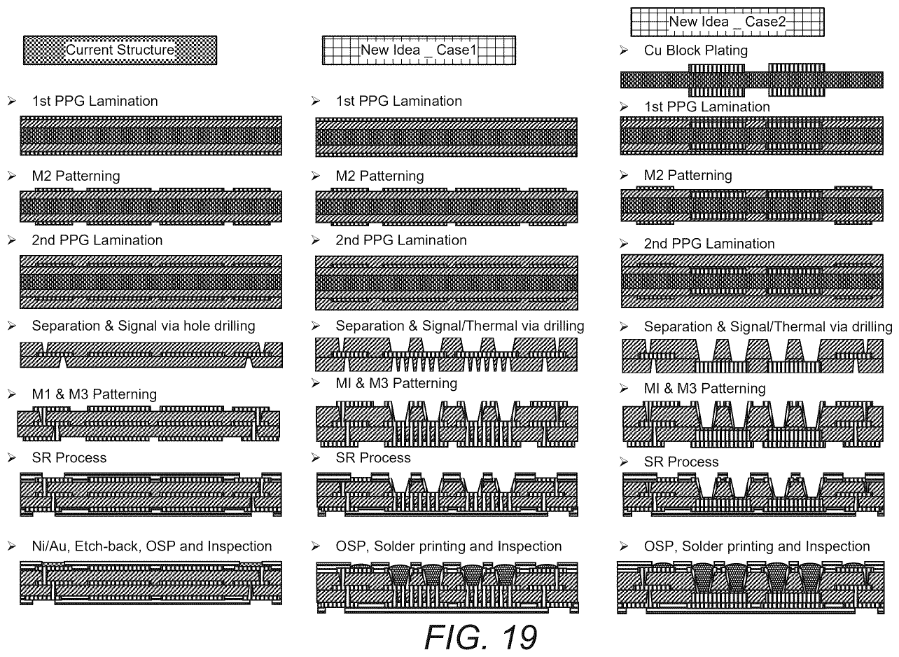

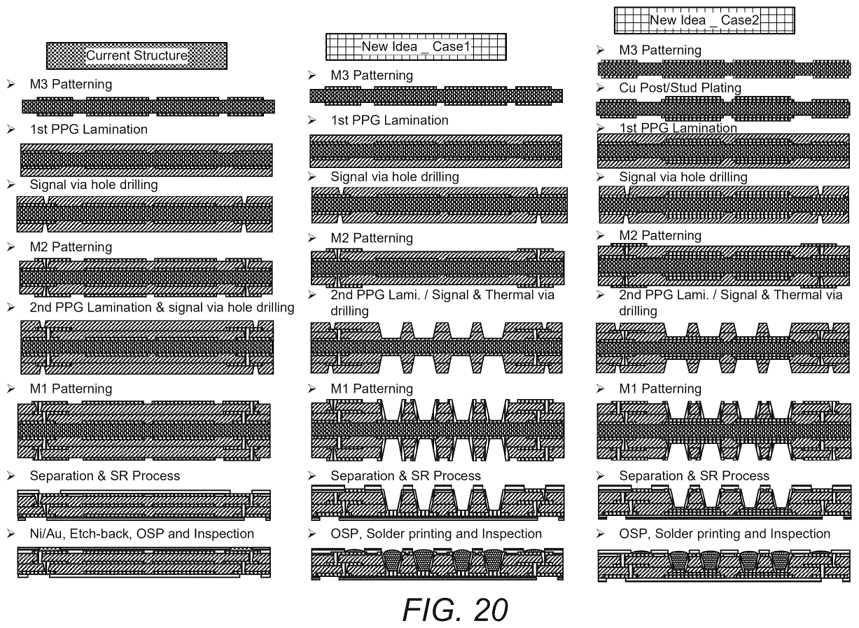

FIG. 12 illustrates a flow chart of an example process to perform block 820 of FIG. 8. The process of FIG. 12 corresponds to the stages illustrated in FIG. 7A-7I.

In block 1210, the third metal layer M3 may be patterned on a carrier 705.

In block 1215, the at least one metal post 386 may be formed on the at least one third layer thermal pad 282.

In block 1220, the second dielectric layer 280 may be formed on the carrier 705, on the third metal layer M3, and on the at least one third layer thermal pad 282.

In block 1230, the second dielectric layer 280 may be drilled to form at least one lower signal via hole 783.

In block 1240, the second metal layer M2 may be patterned on the second dielectric layer 280.

In block 1250, the first dielectric layer 270 may be formed on the second dielectric layer 280 and on the second metal layer M2.

In block 1255, the first dielectric layer 270 and the second dielectric layer 280 may be drilled to form at least one thermal solder via hole 774 to expose an upper surface of the at least one metal post 386.

In block 1260, the first metal layer M1 may be patterned on the first dielectric layer 270 and in the at least one thermal solder via hole 774. The at least one thermal via metal 376 may be formed.

In block 1270, solder resist (SR) 290 may be formed on the upper surface of the first dielectric layer 270 or on the lower surface of the second dielectric layer 280 or both.

In block 1280, the at least one thermal solder via hole 774 may be filled with solder to form the at least one thermal solder via 274.

The following should be noted regarding the flow indicated in FIG. 8-12. Unless otherwise indicated, the flow of blocks do not necessarily limit the ordering in which the blocks may be performed. In other words, the blocks may be performed in any order that is logical.

FIG. 13 illustrates various apparatuses (e.g., electronic devices) in which any of the semiconductor devices and/or electronic packages disclosed herein may be integrated, according to aspects of the disclosure. In an aspect, the semiconductor devices and/or electronic packages 1300 may be integrated into user equipment (UE), including, by way of example and not limitation, a mobile phone device 1302, a laptop computer device 1304, a fixed-location terminal device 1306, or a wearable device 1308.

In other aspects, the semiconductor devices and/or electronic packages 1300 may be integrated into electronic devices utilized in automotive applications. Such devices may include, by way of example and not limitation, sensors, controllers, processors, infotainment devices, and the like, which may be installed in a vehicle 1310.

In yet other aspects, the semiconductor devices and/or electronic packages 1300 may be integrated into a short-range device (SRD) 1312. The SRD 1312 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 1300 may be integrated into a server 1314. The server 1314 may comprise a computer system configured to provide services, data, or resources to other computers over a network. Such a server 1314 may include one or more processors, integrated memory devices, power supplies, or other components mounted in one or more racks.

In yet other aspects, the semiconductor devices and/or electronic packages 1300 may be integrated into a data center 1316. The data center 1316 may comprise a facility configured with one or more servers, storage devices, networking devices, and other supporting devices for storing, processing, and managing data.

The semiconductor devices and/or electronic packages 1300 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 1302, 1304, 1306, 1308, 1310, 1312, 1314, and 1316 illustrated in FIG. 13 are merely exemplary. Other apparatuses in which the semiconductor devices and/or electronic packages 1300 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A die package, comprising: a first die; an interposer substrate on the first die; and a second die on the interposer substrate, wherein the second die comprises a ball grid array (BGA) on a lower surface of the second die, the BGA comprising at least one signal ball and at least one thermal ball, the at least one signal ball configured to carry electrical signal to and/or from the second die, wherein the interposer substrate comprises: a first dielectric layer stacked on a second dielectric layer; and at least one thermal solder via within the first dielectric layer, wherein a top portion of the at least one thermal solder via is above an upper surface of the first dielectric layer, and wherein the at least one thermal solder via is thermally coupled to the at least one thermal ball.
Clause 2: The die package of clause 1, wherein the at least one thermal solder via is in physical contact with the at least one thermal ball.
Clause 3: The die package of any of clauses 1-2, wherein the at least one thermal ball does not carry any signal to/from the second die.
Clause 4: The die package of any of clauses 1-3, wherein the interposer substrate further comprises: a first metal layer (M1) on the upper surface of the first dielectric layer; a second metal layer (M2) within the first dielectric layer and on the second dielectric layer; a third metal layer (M3) on a lower surface of the second dielectric layer and above the first die, wherein at least one third layer thermal pad is formed from the third metal layer (M3), and wherein the at least one third layer thermal pad is thermally coupled to the at least one thermal via.
Clause 5: The die package of clause 4, wherein at least one second layer thermal pad is formed from the second metal layer (M2), wherein the interposer substrate further comprises a plurality of lower thermal vias within the second dielectric layer, and wherein a lower surface of the at least one thermal solder via is in physical contact with an upper surface of the at least one second layer thermal pad, and wherein the plurality of lower thermal vias is in physical contact with a lower surface of the at least one second layer thermal pad and with an upper surface of the at least one third layer thermal pad.
Clause 6: The die package of clause 4, wherein the interposer substrate further comprises: at least one thermal via metal on side and lower surfaces of the at least one thermal solder via; and at least one metal block within the second dielectric layer, wherein the at least one metal block is in physical contact with a lower surface of the at least one thermal via metal and with an upper surface of the at least one third layer thermal pad.
Clause 7: The die package of clause 4, wherein the thermal solder via is within the first and second dielectric layers, wherein the interposer substrate further comprises at least one thermal via metal on side and lower surfaces of the at least one thermal solder via, and wherein the at least one third layer thermal pad is in physical contact with a lower surface of the at least one thermal via metal.
Clause 8: The die package of clause 4, wherein the thermal solder via is within the first and second dielectric layers, wherein the interposer substrate further comprises: at least one thermal via metal on side and lower surfaces of the at least one thermal solder via; and at least one metal post within the second dielectric layer, and wherein the at least one metal post is in physical contact with a lower surface of the at least one thermal via metal and with an upper surface of the at least one third layer thermal pad.
Clause 9: The die package of any of clauses 1-8, wherein at least one first layer signal pad is formed from the first metal layer (M1), wherein the die package further comprises a solder finish on the at least one first layer signal pad, wherein an upper portion of the solder finish is in physical contact with the at least one signal ball and a lower portion of the solder finish is in physical contact with the at least one first layer signal pad.
Clause 10: The die package of any of clauses 1-9, wherein the die package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.
Clause 11: A method of fabricating a die package, the method comprising: providing a first die; forming an interposer substrate on the first die; and providing a second die on the interposer substrate, wherein the second die comprises a ball grid array (BGA) on a lower surface of the second die, the BGA comprising at least one signal ball and at least one thermal ball, the at least one signal ball configured to carry electrical signal to and/or from the second die, wherein the interposer substrate comprises: a first dielectric layer stacked on a second dielectric layer; and at least one thermal solder via within the first dielectric layer, wherein a top portion of the at least one thermal solder via is above an upper surface of the first dielectric layer, and wherein the at least one thermal solder via is thermally coupled to the at least one thermal ball.
Clause 12: The method of clause 11, wherein the at least one thermal solder via is in physical contact with the at least one thermal ball.
Clause 13: The method of any of clauses 11-12, wherein the at least one thermal ball does not carry any signal to/from the second die.
Clause 14: The method of any of clauses 11-13, wherein the interposer substrate further comprises: a first metal layer (M1) on the upper surface of the first dielectric layer; a second metal layer (M2) within the first dielectric layer and on the second dielectric layer; a third metal layer (M3) on a lower surface of the second dielectric layer and above the first die, wherein at least one third layer thermal pad is formed from the third metal layer (M3), and wherein the at least one third layer thermal pad is thermally coupled to the at least one thermal via.
Clause 15: The method of clause 14, wherein at least one second layer thermal pad is formed from the second metal layer (M2), wherein the interposer substrate further comprises a plurality of lower thermal vias within the second dielectric layer, and wherein a lower surface of the at least one thermal solder via is in physical contact with an upper surface of the at least one second layer thermal pad, and wherein the plurality of lower thermal vias is in physical contact with a lower surface of the at least one second layer thermal pad and with an upper surface of the at least one third layer thermal pad.
Clause 16: The method of clause 15, wherein forming the interposer substrate comprises: forming the second dielectric layer on a carrier; patterning the second metal layer (M2) on the second dielectric layer; forming the first dielectric layer on the second dielectric layer and on the second metal layer (M2); drilling the first dielectric layer to form at least one thermal solder via hole to expose the upper surface of the at least one second layer thermal pad; drilling the second dielectric layer to form a plurality of lower thermal via holes to expose the lower surface of the at least one second layer thermal pad; patterning the first metal layer (M1) on the first dielectric layer and in the at least one thermal solder via hole, wherein at least one thermal via metal is formed on sides of the at least one thermal solder via hole; patterning the third metal layer (M3) on the lower surface of the second dielectric layer and in the plurality of lower thermal via holes, wherein the plurality of lower thermal vias are formed in the plurality of lower thermal via holes; forming solder resist (SR) on the upper surface of the first dielectric layer or on the lower surface of the second dielectric layer or both; and filling the at least one thermal solder via hole with solder to form the at least one thermal solder via.
Clause 17: The method of clause 14, wherein the interposer substrate further comprises: at least one thermal via metal on side and lower surfaces of the at least one thermal solder via; and at least one metal block within the second dielectric layer, wherein the at least one metal block is in physical contact with a lower surface of the at least one thermal via metal and with an upper surface of the at least one third layer thermal pad.
Clause 18: The method of clause 17, wherein forming the interposer substrate comprises: forming at least one metal block on a carrier; forming the second dielectric layer on the carrier and on the at least one metal block; patterning the second metal layer (M2) on the second dielectric layer; forming the first dielectric layer on the second dielectric layer and on the second metal layer (M2); drilling the first dielectric layer and the second dielectric layer to form at least one thermal solder via hole to expose upper surface of the at least one metal block; patterning the first metal layer (M1) on the first dielectric layer, wherein the at least one thermal via metal is formed; patterning the third metal layer (M3) on the lower surface of the second dielectric layer and on a lower surface of the at least one metal block; forming solder resist (SR) on the upper surface of the first dielectric layer or on the lower surface of the second dielectric layer or both; and filling the at least one thermal solder via hole with solder to form the at least one thermal solder via.
Clause 19: The method of clause 14, wherein the thermal solder via is within the first and second dielectric layers, wherein the interposer substrate further comprises at least one thermal via metal on side and lower surfaces of the at least one thermal solder via, and wherein the at least one third layer thermal pad is in physical contact with a lower surface of the at least one thermal via metal.
Clause 20: The method of clause 19, wherein forming the interposer substrate comprises: patterning the third metal layer (M3) on a carrier; forming the second dielectric layer on the carrier and on the third metal layer (M2); drilling the second dielectric layer to form at least one lower signal via hole; patterning the second metal layer (M2) on the second dielectric layer; forming the first dielectric layer on the second dielectric layer and on the second metal layer (M2); drilling the first dielectric layer and the second dielectric layer to form at least one thermal solder via hole to expose an upper surface of the third layer thermal pad; patterning the first metal layer (M1) on the first dielectric layer and in the at least one thermal solder via hole, wherein the at least one thermal via metal is formed; forming solder resist (SR) on the upper surface of the first dielectric layer or on the lower surface of the second dielectric layer or both; and filling the at least one thermal solder via hole with solder to form the at least one thermal solder via.
Clause 21: The method of clause 14, wherein the thermal solder via is within the first and second dielectric layers, wherein the interposer substrate further comprises: at least one thermal via metal on side and lower surfaces of the at least one thermal solder via; and at least one metal post within the second dielectric layer, and wherein the at least one metal post is in physical contact with a lower surface of the at least one thermal via metal and with an upper surface of the at least one third layer thermal pad.
Clause 22: The method of clause 21, wherein forming the interposer substrate comprises: patterning the third metal layer (M3) on a carrier; forming the at least one metal post on the at least one third layer thermal pad; forming the second dielectric layer on the carrier, on the third metal layer (M3), and on the at least one third layer thermal pad; drilling the second dielectric layer to form at least one lower signal via hole; patterning the second metal layer (M2) on the second dielectric layer; forming the first dielectric layer on the second dielectric layer and on the second metal layer (M2); drilling the first dielectric layer and the second dielectric layer to form at least one thermal solder via hole to expose an upper surface of the at least one metal post; patterning the first metal layer (M1) on the first dielectric layer and in the at least one thermal solder via hole, wherein the at least one thermal via metal is formed; forming solder resist (SR) on the upper surface of the first dielectric layer or on the lower surface of the second dielectric layer or both; and filling the at least one thermal solder via hole with solder to form the at least one thermal solder via.
Clause 23: The method of any of clauses 11-22, wherein at least one first layer signal pad is formed from the first metal layer (M1), wherein the method further comprises forming a solder finish on the at least one first layer signal pad, wherein an upper portion of the solder finish is in physical contact with the at least one signal ball and a lower portion of the solder finish is in physical contact with the at least one first layer signal pad.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A die package, comprising:
a first die;
an interposer substrate on the first die; and
a second die on the interposer substrate,
wherein the second die comprises a ball grid array (BGA) on a lower surface of the second die, the BGA comprising at least one signal ball and at least one thermal ball, the at least one signal ball configured to carry electrical signal to and/or from the second die,
wherein the interposer substrate comprises:
a first dielectric layer stacked on a second dielectric layer; and
at least one thermal solder via within the first dielectric layer,
wherein a top portion of the at least one thermal solder via is above an upper surface of the first dielectric layer, and
wherein the at least one thermal solder via is thermally coupled to the at least one thermal ball.

2. The die package of claim 1, wherein the at least one thermal solder via is in physical contact with the at least one thermal ball.

3. The die package of claim 1, wherein the at least one thermal ball does not carry any signal to/from the second die.

4. The die package of claim 1, wherein the interposer substrate further comprises:
a first metal layer (M1) on the upper surface of the first dielectric layer;
a second metal layer (M2) within the first dielectric layer and on the second dielectric layer; and
a third metal layer (M3) on a lower surface of the second dielectric layer and above the first die,
wherein at least one third layer thermal pad is formed from the third metal layer (M3), and
wherein the at least one third layer thermal pad is thermally coupled to the at least one thermal via.

5. The die package of claim 4,
wherein at least one second layer thermal pad is formed from the second metal layer (M2),
wherein the interposer substrate further comprises a plurality of lower thermal vias within the second dielectric layer, and
wherein a lower surface of the at least one thermal solder via is in physical contact with an upper surface of the at least one second layer thermal pad, and
wherein the plurality of lower thermal vias is in physical contact with a lower surface of the at least one second layer thermal pad and with an upper surface of the at least one third layer thermal pad.

6. The die package of claim 4, wherein the interposer substrate further comprises:
at least one thermal via metal on side and lower surfaces of the at least one thermal solder via; and
at least one metal block within the second dielectric layer,
wherein the at least one metal block is in physical contact with a lower surface of the at least one thermal via metal and with an upper surface of the at least one third layer thermal pad.

7. The die package of claim 4,
wherein the thermal solder via is within the first and second dielectric layers,
wherein the interposer substrate further comprises at least one thermal via metal on side and lower surfaces of the at least one thermal solder via, and
wherein the at least one third layer thermal pad is in physical contact with a lower surface of the at least one thermal via metal.

8. The die package of claim 4,
wherein the thermal solder via is within the first and second dielectric layers,
wherein the interposer substrate further comprises:
at least one thermal via metal on side and lower surfaces of the at least one thermal solder via; and
at least one metal post within the second dielectric layer, and
wherein the at least one metal post is in physical contact with a lower surface of the at least one thermal via metal and with an upper surface of the at least one third layer thermal pad.

9. The die package of claim 1,
wherein at least one first layer signal pad is formed from the first metal layer (M1),
wherein the die package further comprises a solder finish on the at least one first layer signal pad, and
wherein an upper portion of the solder finish is in physical contact with the at least one signal ball and a lower portion of the solder finish is in physical contact with the at least one first layer signal pad.

10. The die package of claim 1, wherein the die package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

11. A method of fabricating a die package, the method comprising:
providing a first die;
forming an interposer substrate on the first die; and
providing a second die on the interposer substrate,
wherein the second die comprises a ball grid array (BGA) on a lower surface of the second die, the BGA comprising at least one signal ball and at least one thermal ball, the at least one signal ball configured to carry electrical signal to and/or from the second die,
wherein the interposer substrate comprises:
a first dielectric layer stacked on a second dielectric layer; and
at least one thermal solder via within the first dielectric layer,
wherein a top portion of the at least one thermal solder via is above an upper surface of the first dielectric layer, and
wherein the at least one thermal solder via is thermally coupled to the at least one thermal ball.

12. The method of claim 11, wherein the interposer substrate further comprises:
a first metal layer (M1) on the upper surface of the first dielectric layer;
a second metal layer (M2) within the first dielectric layer and on the second dielectric layer; and
a third metal layer (M3) on a lower surface of the second dielectric layer and above the first die,
wherein at least one third layer thermal pad is formed from the third metal layer (M3), and
wherein the at least one third layer thermal pad is thermally coupled to the at least one thermal via.

13. The method of claim 12,
wherein at least one second layer thermal pad is formed from the second metal layer (M2),
wherein the interposer substrate further comprises a plurality of lower thermal vias within the second dielectric layer, and
wherein a lower surface of the at least one thermal solder via is in physical contact with an upper surface of the at least one second layer thermal pad, and
wherein the plurality of lower thermal vias is in physical contact with a lower surface of the at least one second layer thermal pad and with an upper surface of the at least one third layer thermal pad.

14. The method of claim 13, wherein forming the interposer substrate comprises:
forming the second dielectric layer on a carrier;
patterning the second metal layer (M2) on the second dielectric layer;
forming the first dielectric layer on the second dielectric layer and on the second metal layer (M2);
drilling the first dielectric layer to form at least one thermal solder via hole to expose the upper surface of the at least one second layer thermal pad;
drilling the second dielectric layer to form a plurality of lower thermal via holes to expose the lower surface of the at least one second layer thermal pad;
patterning the first metal layer (M1) on the first dielectric layer and in the at least one thermal solder via hole, wherein at least one thermal via metal is formed on sides of the at least one thermal solder via hole;
patterning the third metal layer (M3) on the lower surface of the second dielectric layer and in the plurality of lower thermal via holes, wherein the plurality of lower thermal vias are formed in the plurality of lower thermal via holes;
forming solder resist (SR) on the upper surface of the first dielectric layer or on the lower surface of the second dielectric layer or both; and
filling the at least one thermal solder via hole with solder to form the at least one thermal solder via.

15. The method of claim 12, wherein the interposer substrate further comprises:
at least one thermal via metal on side and lower surfaces of the at least one thermal solder via; and
at least one metal block within the second dielectric layer,
wherein the at least one metal block is in physical contact with a lower surface of the at least one thermal via metal and with an upper surface of the at least one third layer thermal pad.

16. The method of claim 15, wherein forming the interposer substrate comprises:
forming at least one metal block on a carrier;
forming the second dielectric layer on the carrier and on the at least one metal block;
patterning the second metal layer (M2) on the second dielectric layer;
forming the first dielectric layer on the second dielectric layer and on the second metal layer (M2);
drilling the first dielectric layer and the second dielectric layer to form at least one thermal solder via hole to expose upper surface of the at least one metal block;
patterning the first metal layer (M1) on the first dielectric layer, wherein the at least one thermal via metal is formed;
patterning the third metal layer (M3) on the lower surface of the second dielectric layer and on a lower surface of the at least one metal block;
forming solder resist (SR) on the upper surface of the first dielectric layer or on the lower surface of the second dielectric layer or both; and
filling the at least one thermal solder via hole with solder to form the at least one thermal solder via.

17. The method of claim 14, wherein forming the interposer substrate comprises:
patterning the third metal layer (M3) on a carrier;
forming the second dielectric layer on the carrier and on the third metal layer (M2);
drilling the second dielectric layer to form at least one lower signal via hole;
patterning the second metal layer (M2) on the second dielectric layer;
forming the first dielectric layer on the second dielectric layer and on the second metal layer (M2);
drilling the first dielectric layer and the second dielectric layer to form at least one thermal solder via hole to expose an upper surface of the third layer thermal pad;
patterning the first metal layer (M1) on the first dielectric layer and in the at least one thermal solder via hole, wherein the at least one thermal via metal is formed;
forming solder resist (SR) on the upper surface of the first dielectric layer or on the lower surface of the second dielectric layer or both; and
filling the at least one thermal solder via hole with solder to form the at least one thermal solder via.

18. The method of claim 12,
wherein the thermal solder via is within the first and second dielectric layers,
wherein the interposer substrate further comprises:
at least one thermal via metal on side and lower surfaces of the at least one thermal solder via; and
at least one metal post within the second dielectric layer, and
wherein the at least one metal post is in physical contact with a lower surface of the at least one thermal via metal and with an upper surface of the at least one third layer thermal pad.

19. The method of claim 18, wherein forming the interposer substrate comprises:
patterning the third metal layer (M3) on a carrier;
forming the at least one metal post on the at least one third layer thermal pad;
forming the second dielectric layer on the carrier, on the third metal layer (M3), and on the at least one third layer thermal pad;
drilling the second dielectric layer to form at least one lower signal via hole;
patterning the second metal layer (M2) on the second dielectric layer;
forming the first dielectric layer on the second dielectric layer and on the second metal layer (M2);
drilling the first dielectric layer and the second dielectric layer to form at least one thermal solder via hole to expose an upper surface of the at least one metal post;
patterning the first metal layer (M1) on the first dielectric layer and in the at least one thermal solder via hole, wherein the at least one thermal via metal is formed;
forming solder resist (SR) on the upper surface of the first dielectric layer or on the lower surface of the second dielectric layer or both; and
filling the at least one thermal solder via hole with solder to form the at least one thermal solder via.

20. The method of claim 11,
wherein at least one first layer signal pad is formed from the first metal layer (M1),
wherein the method further comprises forming a solder finish on the at least one first layer signal pad,
wherein an upper portion of the solder finish is in physical contact with the at least one signal ball and a lower portion of the solder finish is in physical contact with the at least one first layer signal pad.
